(19) United States
(12) Patent Application Publication
(10) Pub. No.: US 2023/0077915 A1
(43) Pub. Date: Mar. 16, 2023

(54) ETCHING METHOD

(71) Applicant: KABUSHIKI KAISHA TOSHIBA, Tokyo (JP)

(72) Inventors: Mitsuo SANO, Kamakura (JP); Susumu OBATA, Yokohama (JP); Kazuhito HIGUCHI, Yokohama (JP); Takayuki TAJIMA, Sagamihara (JP)

(73) Assignee: KABUSHIKI KAISHA TOSHIBA, Tokyo (JP)

(21) Appl. No.: 17/654,924

(22) Filed: Mar. 15, 2022

(30) Foreign Application Priority Data
Sep. 14, 2021 (JP) 2021-149341

(51) Int. Cl. C23C 18/18; H01L 21/306; C23C 18/54; C09K 13/06

(52) U.S. Cl. CPC C23C 18/1889; H01L 21/30604; C23C 18/1879; C23C 18/1882; C23C 18/54; C09K 13/06

(57) ABSTRACT

According to one embodiment, an etching method includes etching a surface made of a semiconductor and having a catalyst layer formed on the surface, by an etching agent in contact with the surface. The catalyst layer contains noble metal. The etching agent contains an oxidizer, a corrosive agent, and a N-containing polymer agent.

### CROSS-REFERENCE TO RELATED APPLICATIONS

This application is based upon and claims the benefit of priority from Japanese Patent Application No. 2021-149341, filed Sep. 14, 2021, the entire contents of which are incorporated herein by reference.

### FIELD

Embodiments described herein relate generally to an etching method.

### BACKGROUND

Etching is known as a method of forming a hole or a groove in a semiconductor wafer. As an etching method, metal-assisted chemical etching (MacEtch) is known. The MacEtch method is, for example, a method of etching a semiconductor substrate using a noble metal as a catalyst. Since a semiconductor wafer is provided with a trench having a high aspect ratio, immersing the semiconductor wafer in a MacEtch solution for a long time causes a processing defect in the form of micropores on a wall surface at the upper end of the trench. As a result, problems such as collapsing of the trench due to a decrease in the strength and difficulty in forming a dielectric film on the trench may occur.

### BRIEF DESCRIPTION OF THE DRAWINGS

FIG. 1 is a schematic diagram showing a step in a method of an embodiment.

FIG. 2 is an enlarged schematic view of section A shown in FIG. 1.

FIG. 3 is a diagram showing a relationship between a pH and a zeta potential of Si oxide.

FIG. 4 is a scanning electron micrograph showing a cross section of a trench formed by the method of the embodiment.

FIG. 5 is a scanning electron micrograph showing a cross section of the vicinity of an upper end of the trench formed by the method of the embodiment.

FIG. 6 is a scanning electron micrograph showing a cross section of a trench formed by a method of a comparative example.

FIG. 7 is a scanning electron micrograph showing a cross section of the vicinity of an upper end of the trench formed by the method of the comparative example.

### DETAILED DESCRIPTION

In general, according to one embodiment, an etching method includes etching a surface made of a semiconductor and having a catalyst layer formed on the surface, by an etching agent in contact with the surface. The catalyst layer contains noble metal. The etching agent contains an oxidizer, a corrosive agent, and a N-containing polymer agent.

Hereinafter, embodiments will be described in detail with reference to the accompanying drawings. The same reference numerals denote constituent elements which achieve the same or similar functions throughout all the drawings, and repeat explanations will be omitted.

### First Embodiment

According to a first embodiment, an etching method is provided. In the etching method, an etching agent is brought into contact with a surface made of a semiconductor and having a catalyst layer containing noble metal formed on the surface, to etch the surface made of a semiconductor. The etching agent contains an oxidizer, a corrosive agent, and a N-containing polymer agent (N-containing polymer additive).

When an etching agent is brought into contact with the surface made of a semiconductor and having a catalyst layer containing noble metal formed on the surface, a portion of the surface close to the noble metal is oxidized by the oxidizer and the resulting oxide is dissolved away by the corrosive agent. Thus, the etching agent may etch the surface made of a semiconductor in a direction perpendicular to the surface with the action of the catalyst layer. Thereby, a trench-like recessed portion can be formed in the surface made of a semiconductor.

It is assumed that generation of a processing defect in the form of pores on the wall surface near an upper end of the trench-like recessed portion is caused by an oxide of a semiconductor material in this area being dissolved in the etching agent by the action of the corrosive agent of the etching agent. Said oxide tends to have a positive zeta potential in the etching agent. On the other hand, the N-containing polymer agent has a lone electron pair of nitrogen atoms. Therefore, the N-containing polymer agent is likely to be adsorbed to the oxide of the semiconductor material in the etching agent, while it is less likely to be adsorbed to a surface of a catalyst having a negative zeta potential. Thus, the N-containing polymer agent can be selectively adsorbed to the vicinity of the upper end of the recessed portion to protect it from the etching agent. Accordingly, even if the surface is immersed in the etching agent for a long time in order to form a recessed portion having a high aspect ratio, generation of a processing defect near the upper end of the recessed portion can be suppressed.

The method of the embodiment will be described in detail below.

The semiconductor is, for example, selected from: silicon (Si); germanium (Ge); a semiconductor made of compounds of group III and group V elements such as gallium arsenide (GaAs) and gallium nitride (GaN); and silicon carbide (SiC). As one example, the semiconductor substrate contains silicon. The term “group” used herein is a “group” in the short form periodic table.

The surface made of a semiconductor may be, for example, a main surface of the semiconductor substrate. The semiconductor substrate is, for example, a semiconductor wafer. The semiconductor wafer may be doped with an impurity or have a semiconductor element such as a transistor or a diode formed thereon. Also, the main surface of the semiconductor wafer may be parallel to any crystal plane of the semiconductor. For example, a silicon wafer whose main surface is a (100) plane or a silicon wafer whose main surface is a (110) plane may be used as the semiconductor wafer.

When forming a pattern having a recessed portion such as a trench on the surface made of a semiconductor, a mask layer having an opening may be formed on the surface made of a semiconductor. Etching processing is performed on the surface exposed from the opening. The mask layer may be formed of an inorganic material such as a silicon nitride compound. The mask layer is prepared, for example, by a method including the following steps. First, the mask layer is formed on the surface made of a semiconductor. A resist layer is formed on the mask layer. For example, the resist layer may be formed of a photoresist. The resist layer is processed into a desired pattern shape to form an opening. The pattern formation is performed by, for example, photolithography. The mask layer is processed into a desired pattern shape by, for example, etching, thereby forming an opening in the mask layer. Next, the resist layer is removed.

The catalyst layer containing noble metal is formed on the surface made of a semiconductor. The catalyst layer may be formed after the mask layer is formed on the surface made of a semiconductor.

In the catalyst layer, the noble metal may exist, for example, in the form of noble metal particles. The noble metal is, for example, at least one metal selected from the group consisting of Au, Ag, Pt, Pd, Ru and Rh.

The thickness of the catalyst layer is preferably in a range of 0.01 μm to 0.3 μm, and more preferably in a range of 0.05 μm to 0.2 μm. If the catalyst layer is too thick, the etching agent is less likely to reach the semiconductor, thus rendering it difficult to cause etching to progress. If the catalyst layer is too thin, the ratio of the total surface area of the noble metal particles to the area to be etched will be too small, thus rendering it difficult to cause etching to progress.

The thickness of the catalyst layer is the distance from one main surface of the catalyst layer to the other main surface of the catalyst layer on the opposite side in an image, observed by a scanning electron microscope (SEM), of the cross section of the catalyst layer that is parallel to the thickness direction of the catalyst layer.

The catalyst layer may include a discontinuous portion.

The noble metal particles are preferably spherical. The noble metal particles may be in any other shape such as a rod shape or a plate shape. The noble metal particles serve as a catalyst for the oxidation reaction of the semiconductor surface that is in contact with the noble metal particles.

The particle size of the noble metal particles is preferably in a range of 0.001 μm to 1 μm, and more preferably in a range of 0.01 μm to 0.5 μm.

The “particle size” is a value obtained by the following method. First, an image of the main surface of the catalyst layer is captured by the scanning electron microscope at a magnification in a range of 10000 to 100000. Then, the area of the noble metal particles is obtained from the image. Subsequently, assuming that the noble metal particles is spherical, the diameter of the noble metal particles is obtained from the foregoing area. This diameter is defined as the “particle size” of the noble metal particles.

The catalyst layer may be a porous catalyst layer.

The catalyst layer can be formed by electroplating, reduction plating, displacement plating, or the like. The catalyst layer may be formed by applying a dispersion liquid containing the noble metal particles, or vapor phase deposition such as evaporation and sputtering. Of these methods, displacement plating is particularly preferable because it can deposit noble metal directly and uniformly on the surface made of a semiconductor. As one example, formation of a porous catalyst layer through displacement plating will be described below.

To deposit noble metal through displacement plating, for example, an aqueous solution of tetrachloroaurate (III) acid or a silver nitrate solution can be used. An example of this process will be described below.

A displacement plating solution is, for example, a mixture of an aqueous solution of hydrogen tetrachloroaurate (III) tetrahydrate and hydrofluoric acid. The hydrofluoric acid has a function of removing a native oxide film from the surface made of a semiconductor.

When the semiconductor substrate is immersed in the displacement plating solution, a native oxide film is removed from the surface of the semiconductor substrate, and noble metal (gold in this example) is also deposited at the surface of the semiconductor substrate. Thus, a porous catalyst layer is obtained.

The concentration of hydrogen tetrachloroaurate (III) tetrahydrate in the displacement plating solution is preferably in a range of 0.0001 mol/L to 0.01 mol/L. The concentration of hydrogen fluoride in the displacement plating solution is preferably in a range of 0.1 mol/L to 6.5 mol/L.

The displacement plating solution may further include a sulfur-based complexing agent. Alternatively, the displacement plating solution may further include glycine and citric acid.

The etching agent will be described below. The etching agent contains a corrosive agent, an oxidizer, and a N-containing polymer agent (N-containing polymer additive).

The corrosive agent may dissolve an oxide of the semiconductor material. The oxide is, for example, SiO₂. The corrosive agent is, for example, hydrofluoric acid or ammonium fluoride. One, two, or more types of corrosive agents may be used. In consideration of the etching rate and the ease of adsorption of the N-containing polymer agent, a corrosive agent containing hydrofluoric acid is preferred.

The concentration of hydrogen fluoride in the etching agent is preferably in a range of 0.4 mol/L to 20 mol/L, more preferably in a range of 0.8 mol/L to 16 mol/L, and still more preferably in a range of 2 mol/L to 10 mol/L. If the concentration of hydrogen fluoride is too low, a high etching rate is difficult to achieve. If the concentration of hydrogen fluoride is too high, controllability of etching in the processing direction (e.g., the thickness direction of the semiconductor substrate) may be lowered.

The oxidizer in the etching agent may be, for example, at least one selected from hydrogen peroxide, nitric acid, AgNO₃, KAuCl₄, HAuCl₄, K₂PtCl₆, H₂PtCl₆, Fe(NO₃)₃, Ni(NO₃)₂, Mg(NO₃)₂, Na₂S₂O₈, K₂S₂O₈, KMnO₄ and K₂Cr₂O₇. Hydrogen peroxide is preferred as the oxidizer because it neither generates any harmful byproduct nor contaminates a semiconductor element.

The concentration of the oxidizer such as hydrogen peroxide in the etching agent is preferably in a range of 0.2 mol/L to 8 mol/L, more preferably in a range of 0.5 mol/L to 5 mol/L, and still more preferably in a range of 0.5 mol/L to 4 mol/L. If the concentration of the oxidizer is too low, a high etching rate is difficult to achieve. If the concentration of the oxidizer is excessively high, excess side etching may occur.

The N-containing polymer agent is not particularly limited so long as it is a polymer containing a nitrogen atom, but may be, for example, a N-containing surfactant. The N-containing surfactant is preferably a N-containing non-ionic surfactant and/or a N-containing cationic surfactant.

Examples of the N-containing cationic surfactant include polyethylenimine, ethylene diamine, diethylene triamine, triethylene tetraamine, tetraethylenepentamine, pentaethylenehexamine, and polyoxyethylene alkylamine. Examples of the N-containing non-ionic surfactant include poly(oxyethylene)octylphenylether and ethylenediamine tetrakis(propoxylate-block-ethoxylate)tetrol.

One, two, or more types of N-containing polymer agents may be used. A preferred N-containing polymer agent is one that includes polyethylenimine.

The content of the N-containing polymer agent in the etching agent may be, for example, 0.0001% by volume to 0.01% by volume. With the content of the N-containing polymer agent being 0.0001% by volume or more, an effect of suppressing a processing defect of the wall surface defining the recessed portion can be expected. With the content of the N-containing polymer agent being 0.01% by volume or less, an extreme decrease in the etching rate can be avoided. A preferred range of the content may be 0.005% by volume to 0.01% by volume.

The etching agent may include water as a solvent. The etching agent may be an aqueous solution.

The etching agent may be an aqueous solution having a pH of 1 to 2, for example. With the pH in this range, it is possible to promote adsorption of the N-containing polymer agent to the oxide of the semiconductor material while maintaining a practical etching rate.

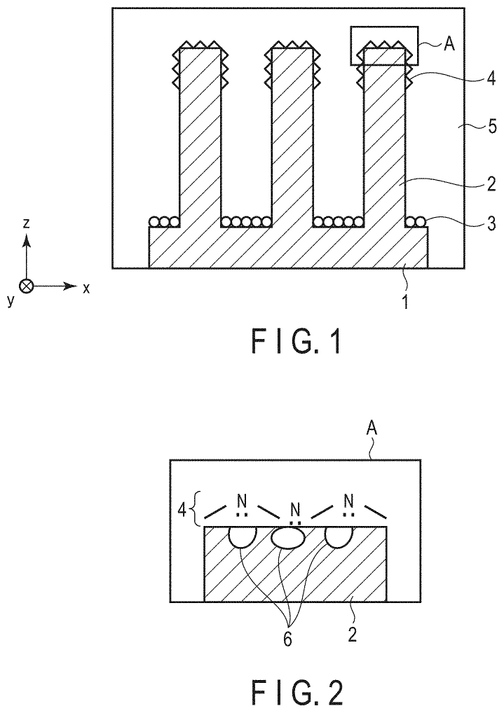

An example of the etching method of the embodiment will be described with reference to FIGS. 1 to 3.

FIG. 1 is a schematic diagram illustrating a process of forming a trench on a main surface of the semiconductor substrate 1 along the xy plane through etching processing. A semiconductor substrate 1 may be, for example, a silicon wafer. Trenches are formed on a main surface of the semiconductor substrate 1 along the xy plane. The trenches extend along the y-axis direction. For example, a catalyst layer 3 containing Au particles is formed on the bottom surface that defines the trenches on the main surface of the semiconductor substrate 1 along the xy plane. A surface near an upper end of walls 2 that define the trenches is coated with a protective layer 4 containing the N-containing polymer agent. The N-containing polymer agent may be, for example, polyethylenimine. The main surface of the semiconductor substrate 1 along the xy plane and the entirety of the walls 2 are immersed in an etching solution 5, which serves as the etching agent.

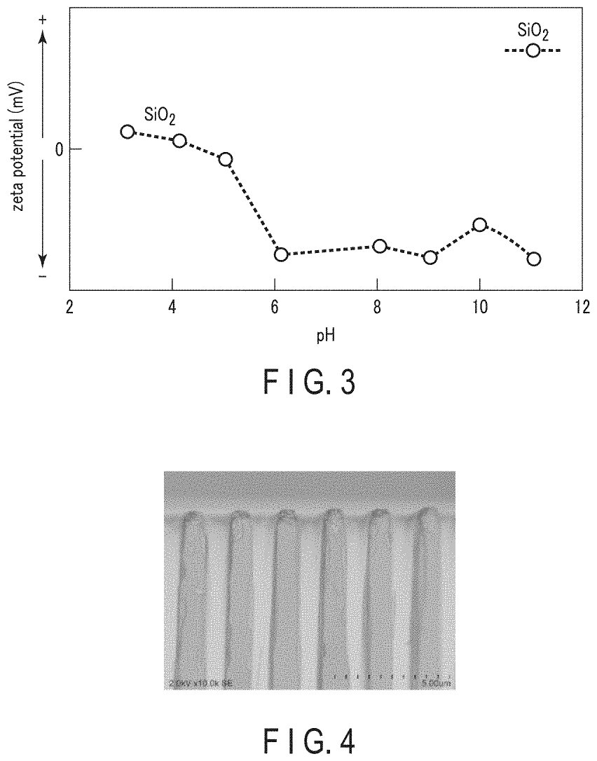

For example, etching is performed after a mask layer having a desired pattern is formed on the main surface of the semiconductor substrate 1. As the etching progresses, a part of the mask layer is dissolved in the etching solution 5 or peeled. Thereby, a part of the upper end surface of the walls 2 directly contacts the etching solution 5. This leads to partial oxidization of the vicinity of the upper end of the walls 2 and formation of a Si oxide 6 such as SiO₂ on a part of the upper end surface of the walls 2, as shown in FIG. 2. The Si oxide 6 such as SiO₂ may have a positive zeta potential in the etching solution. FIG. 3 shows a relationship between the zeta potential of the SiO₂ particle surface and the pH. The horizontal axis of FIG. 3 represents the pH, and the vertical axis of FIG. 3 represents the zeta potential (mV). As shown in FIG. 3, the zeta potential of the SiO₂ particle surface takes a positive value when the pH is 4 or less. The zeta potential of the Si surface takes a negative value when the pH is 4 or less.

On the other hand, since the N-containing polymer agent such as polyethylenimine has many lone electron pairs, the N-containing polymer agent is likely to be adsorbed to the Si oxide 6, which has a positive zeta potential in the etching solution 5. In contrast, the N-containing polymer agent such as polyethylenimine cannot be adsorbed to the surface of a catalyst, which may have a negative zeta potential in the etching solution 5, or to the semiconductor surface, and thus does not inhibit processing. For example, Au has a zeta potential of −20.4 mV at a pH of 1 to 2.

From the foregoing, since the protective layer 4 containing the N-containing polymer agent can be selectively adsorbed to the Si oxide 6 existing near the upper end of the walls 2, it is possible to perform etching while protecting the vicinity of the upper end of the walls 2 from the etching solution 5. Thus, even when a trench having a high aspect ratio is formed, it is possible to suppress generation of a processing defect in the walls 2. This effect cannot be achieved when polyethylenimine is contained in the catalyst layer 3 instead of in the etching agent. For example, when a dispersion liquid containing Au particles and polyethylenimine is applied to the main surface of the semiconductor substrate 1 and dried to thereby form the catalyst layer 3, increasing the immersion time into the etching solution does not lead to progression of the etching processing in the direction perpendicular to the main surface of the semiconductor, rendering it impossible to obtain a trench having a high aspect ratio. The depth of the trench that allows for processing in the perpendicular direction is approximately several tens of micrometers at maximum.

The method of the embodiment may include a step of removing the N-containing polymer agent from the surface made of semiconductor (i.e., semiconductor surface) after the etching step. Examples of the method of removing the N-containing polymer agent include washing the semiconductor surface with an aqueous solution of alkali or an organic solvent. The method of the embodiment may include, as necessary, a step of removing the catalyst layer from the semiconductor surface after the etching step. If there is a mask layer residue, the method of the embodiment may include the step of removing the mask layer from the semiconductor surface. If the method of the embodiment includes the step of removing the catalyst layer from the semiconductor surface or the step of removing the mask layer from the semiconductor surface, the N-containing polymer agent can be removed in these steps. For example, aqua regia can be used to remove the catalyst layer. On the other hand, hot phosphoric acid or the like can be used to remove the mask layer.

The method of the embodiment can be applied to, for example, a pattern forming method in which a recessed portion such as a trench or a through-hole is formed in the semiconductor substrate. The method of the embodiment can manufacture a semiconductor device by forming a conductive layer, by plating, in the recessed portion or the through-hole formed in the semiconductor substrate, or undergoing a step of forming a dielectric film or forming an interconnect layer above the semiconductor substrate by chemical vapor phase deposition (CVD).

### EXAMPLES

An example and a comparative example will be described below.

### Example

A trench was formed by performing etching processing on a semiconductor substrate, by the method described below. After the etching, whether or not damage in the form of pores occurred in the wall surface of the trench was checked.

A silicon wafer was used as the semiconductor substrate. First, a mask layer made of a silicon nitride compound was formed on a first main surface of the semiconductor substrate. The mask layer had openings provided thereto with a certain distance between them.

A 50 mL plating solution containing an aqueous solution of hydrogen tetrachloroaurate (III) tetrahydrate and hydrofluoric acid was prepared. The semiconductor substrate with the mask layer formed thereon was immersed in the plating solution at an ambient temperature for 60 seconds to form a catalyst layer on the first main surface exposed from the openings of the mask layer.

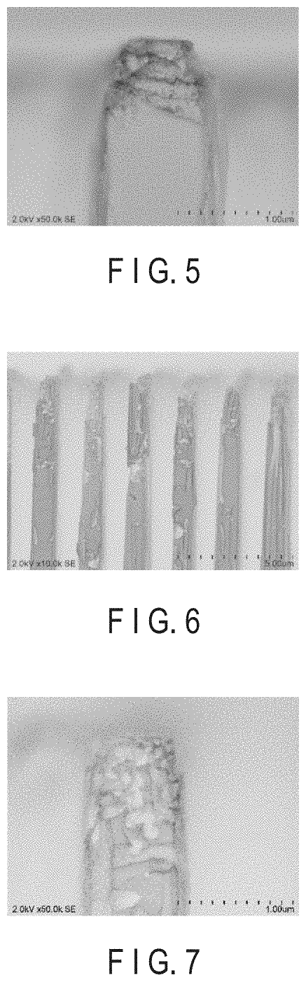

An aqueous solution containing 5 mol/L of hydrogen fluoride, 4 mol/L of hydrogen peroxide, and 0.0001% by volume of polyethylenimine was prepared as an etching solution. The semiconductor substrate with the mask layer and the catalyst layer formed thereon was immersed in the etching solution at 25° C. for 50 minutes and etched. The pH of the etching solution was 1 or less. FIG. 4 shows a scanning electron micrograph of the semiconductor substrate after the etching. FIG. 5 shows an enlarged scanning electron micrograph of the vicinity of an upper end of walls defining the trench of the semiconductor substrate shown in FIG. 4.

No processing defect was observed on the surface of the walls defining the trench of the semiconductor substrate, as shown in FIG. 4. Even in the enlarged view of the vicinity of the upper end of the walls, no processing defect was observed on the surface of the walls, as shown in FIG. 5.

### Comparative Example

An etching solution was prepared which had the same composition and pH as those of the example except for the absence of polyethylenimine. Etching was performed in the same manner as described in the example except for the use of this etching solution. FIG. 6 shows a scanning electron micrograph of the semiconductor substrate after the etching. FIG. 7 shows an enlarged scanning electron micrograph of the vicinity of an upper end of walls defining the trench of the semiconductor substrate shown in FIG. 6.

A processing defect was observed on the surface of the walls defining the trench of the semiconductor substrate, as shown in FIG. 6. In the enlarged view of the vicinity of the upper end of the walls, a processing defect was observed on the entire vicinity of the upper end of the walls, as shown in FIG. 7.

According to the method of at least one embodiment or example described above, an etching agent containing an oxidizer, a corrosive agent, and a N-containing polymer agent is used in a method of etching a surface made of a semiconductor and having a catalyst layer containing noble metal formed on the surface, by bringing an etching agent into contact with the surface; thus, it is possible to provide an etching method capable of reducing a processing defect.

Supplemental embodiments are described below.

According to an embodiment, there is provided an etching method including etching a surface made of a semiconductor and having a catalyst layer formed on the surface, by an etching agent in contact with the surface, the catalyst layer containing noble metal, wherein the etching agent contains an oxidizer, a corrosive agent, and a N-containing polymer agent.

According to an embodiment, there is provided a pattern forming method including forming a recessed portion on a surface made of a semiconductor and having a catalyst layer formed on the surface, by an etching agent in contact with the surface, the catalyst layer containing noble metal, wherein the etching agent contains an oxidizer, a corrosive agent, and a N-containing polymer agent.

Also, according to an embodiment, there is provided a method for manufacturing a semiconductor device, the method including: forming a recessed portion in a semiconductor substrate having a catalyst layer formed on the substrate, by an etching agent in contact with the semiconductor substrate, the etching agent containing an oxidizer, a corrosive agent, and a N-containing polymer agent, the catalyst layer containing noble metal; and

forming an interconnect layer above the semiconductor substrate.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. An etching method comprising:
etching a surface made of a semiconductor and having a catalyst layer formed on the surface, by an etching agent in contact with the surface, the catalyst layer containing noble metal,
wherein the etching agent contains an oxidizer, a corrosive agent, and a N-containing polymer agent.

2. The etching method according to claim 1, wherein the N-containing polymer agent is a N-containing surfactant.

3. The etching method according to claim 1, wherein the N-containing polymer agent is a N-containing non-ionic surfactant and/or a N-containing cationic surfactant.

4. The etching method according to claim 1, wherein the N-containing polymer agent is at least one selected from the group consisting of polyethylenimine, ethylene diamine, diethylene triamine, triethylene tetraamine, tetraethylenepentamine, pentaethylenehexamine, polyoxyethylene alkylamine, poly(oxyethylene)octylphenylether, and ethylenediamine tetrakis(propoxylate-block-ethoxylate)tetrol.

5. The etching method according to claim 1, wherein the semiconductor includes silicon.

6. The etching method according to claim 1, wherein the noble metal includes gold.

7. The etching method according to claim 1, wherein the catalyst layer containing noble metal is porous.

8. The etching method according to claim 1, wherein the catalyst layer containing noble metal is formed by displacement plating.

9. The etching method according to claim 1, wherein the oxidizer is hydrogen peroxide, and the corrosive agent is hydrogen fluoride.
